(19) United States
(12) Patent Application Publication
(10) Pub. No.: US 2023/0058776 A1
(43) Pub. Date: Feb. 23, 2023

(54) DISPLAY DEVICE AND METHOD OF MANUFACTURING THE SAME

(71) Applicant: SAMSUNG DISPLAY CO., LTD., Yongin-si (KR)

(72) Inventors: Jun Young LEE, Yongin-si (KR); Si Joon SONG, Yongin-si (KR)

(21) Appl. No.: 17/837,484

(22) Filed: Jun. 10, 2022

(30) Foreign Application Priority Data
Aug. 20, 2021 (KR) 10-2021-0110425

(51) Int. Cl. H01L 25/16; H01L 23/31; H01L 21/56

(52) U.S. Cl. CPC H01L 25/162; H01L 23/3157; H01L 21/568; H01L 2224/24051; H01L 2224/24145; H01L 2224/245; H01L 2924/0549; H01L 24/24

(57) ABSTRACT

A display device includes a display substrate including a display area and a non-display area, a film substrate at least partially overlapping the non-display area of the display substrate, a driving chip located the film substrate, a film layer at a side surface of the display substrate, an adhesive layer between the film layer and a first surface of the film substrate, and a resin layer covering a second surface of the film substrate and a portion of an upper surface of the display substrate, wherein a portion of the resin layer and a portion of the film substrate are bent to the side surface of the display substrate.

### CROSS-REFERENCE TO RELATED APPLICATION

This application claims priority to, and the benefit of, Korean patent application number 10-2021-0110425 filed on Aug. 20, 2021, the entire disclosure of which is incorporated herein in its entirety by reference.

### BACKGROUND

### 1. Field

Various embodiments of the present disclosure relate to a display device, and to a method of manufacturing the display device.

### 2. Related Art

With an increase in interest in information displays and an increase in demand to use portable information media, demand for display devices is markedly increased, and commercialization thereof is in progress.

### SUMMARY

Various embodiments of the present disclosure are directed to a frameless display device, and to a method of manufacturing the display device in a simple manner.

One or more embodiments of the present disclosure may provide for a display device including a display substrate including a display area and a non-display area, a film substrate at least partially overlapping the non-display area of the display substrate, a driving chip located the film substrate, a film layer at a side surface of the display substrate, an adhesive layer between the film layer and a first surface of the film substrate, and a resin layer covering a second surface of the film substrate and a portion of an upper surface of the display substrate, wherein a portion of the resin layer and a portion of the film substrate are bent to the side surface of the display substrate.

The display device may further include an overcoat layer above an upper surface of the display substrate, and at least partially overlapping the display substrate, and a protective film above an upper surface of the overcoat layer, and at least partially overlapping the overcoat layer.

The resin layer may cover the second surface of the film substrate and a portion of the overcoat layer, and to contact a side surface of the protective film.

The resin layer may fill a space between the overcoat layer and the film substrate.

An upper surface of the resin layer and an upper surface of the protective film may be at substantially a same plane.

The film layer may include polyethylene terephthalate.

The adhesive layer may include an optically clear adhesive layer.

One or more embodiments of the present disclosure may provide for a method of manufacturing a display device including preparing a display substrate and a film substrate configured to at least partially overlap an upper surface of the display substrate, attaching a guide film to a lower surface of the film substrate, applying a resin layer onto an upper surface of the film substrate and a portion of an upper surface of the display substrate, removing a portion of the guide film, and bending a portion of the resin layer, a remaining portion of the guide film, and a portion of the film substrate to a side surface of the display substrate.

The guide film may include a support layer, a film layer, and an adhesive layer that are successively stacked, wherein the guide film is attached so that an upper surface of the adhesive layer is at the lower surface of the film substrate.

The removed portion of the guide film may include the support layer.

Applying the resin layer may include applying the resin layer by a slit nozzle method.

The method may further include irradiating an upper surface of the resin layer with ultraviolet rays after removing the portion of the guide film.

The method may further include irradiating the upper surface of the resin layer with ultraviolet rays after bending the remaining portion of the guide film, and the portion of the film substrate to the side surface of the display substrate.

The guide film may include a support layer, a film layer, an ink layer, and an adhesive layer that are successively stacked, wherein the guide film is attached so that an upper surface of the adhesive layer is at the lower surface of the film substrate.

The removed portion of the guide film may include the support layer.

One or more embodiments of the present disclosure may provide for a display device including a display substrate including a display area and a non-display area, a film substrate at least partially overlapping the non-display area of the display substrate, a driving chip located on the film substrate, a film layer at a side surface of the display substrate, an adhesive layer between the film layer and a first surface of the film substrate, an ink layer between the film layer and the adhesive layer, and a resin layer covering a second surface of the film substrate and a portion of an upper surface of the display substrate, wherein a portion of the resin layer and a portion of the film substrate are bent to the side surface of the display substrate.

The display device may further include an overcoat layer above the upper surface of the display substrate, and at least partially overlapping the display substrate, and a protective film above an upper surface of the overcoat layer, and at least partially overlapping the overcoat layer.

The resin layer may cover a portion of the overcoat layer, and contact a side surface of the protective film.

The resin layer may fill a space between the overcoat layer and the film substrate.

An upper surface of the resin layer and an upper surface of the protective film may be at substantially a same plane.

### BRIEF DESCRIPTION OF THE DRAWINGS

FIG. 1 is a plan view schematically illustrating a display device in accordance with one or more embodiments.

FIG. 2 is a sectional view illustrating a display device in accordance with one or more embodiments.

FIGS. 3 to 10 are drawings illustrating a method of manufacturing a display device in accordance with one or more embodiments.

FIGS. 11 and 12 are perspective views illustrating a method of manufacturing a display device in accordance with one or more embodiments.

FIG. 13 is a sectional view illustrating a display device in accordance with one or more embodiments.

FIGS. 14 to 17 are drawings illustrating a method of manufacturing a display device in accordance with one or more embodiments.

FIG. 18 is a sectional view illustrating a pixel of a display device in accordance with one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

When one or more embodiments may be implemented differently, a specific process order may be performed differently from the described order. For example, two consecutively described processes may be performed substantially at the same time or performed in an order opposite to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

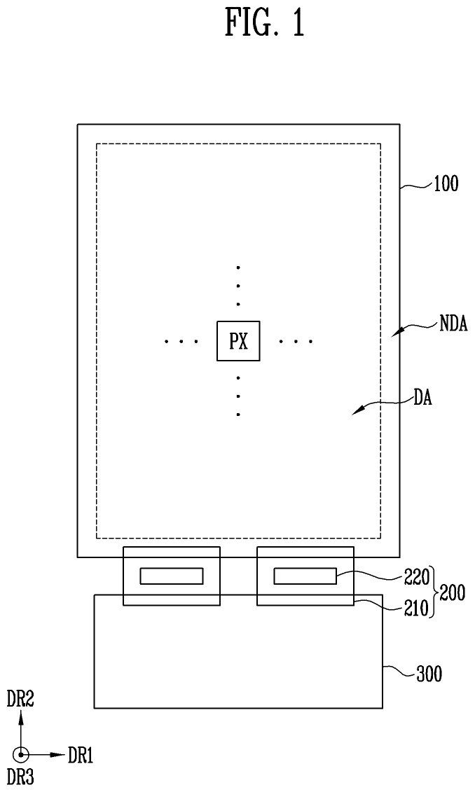

FIG. 1 is a plan view schematically illustrating a display device in accordance with one or more embodiments.

Referring to FIG. 1, a display device in accordance with one or more embodiments may include a display substrate 100, a film substrate 210, a driving chip 220, and a printed circuit board 300.

The display substrate 100 may include a base layer including a transparent insulating material, a driving circuit positioned on the base layer, a display element, and the like. The base layer may include a rigid material or a flexible material. In one or more embodiments, the base layer may be implemented as a glass display substrate including the rigid material.

The display substrate 100 may include a display area DA on which an image is displayed, and a non-display area NDA on which an image is not displayed.

The display area DA may include pixels PX for displaying the image. Each of the pixels PX may include a plurality of transistors, a light emitting element, and a capacitor.

The non-display area NDA may be provided on at least one side of the display area DA. The non-display area NDA may enclose a periphery of the display area DA. Lines electrically connected to the pixels PX, and a plurality of pads connected to the lines, may be positioned in the non-display area NDA. The lines may electrically connect the film substrate 210 and the pixels PX.

The display substrate 100 may be provided in the shape of a rectangular plate. The present disclosure is not limited thereto. That is, the display substrate 100 may be provided in the shape of a square or circle plate, and may be provided in a rectangular shape having a rounded corner.

The display substrate 100 in accordance with one or more embodiments may be applied to a display substrate of an electronic device having on at least one surface thereof a display surface, such as a smart phone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, or a wearable display device.

The film substrate 210 may at least partially overlap the display substrate 100, and may at least partially overlap the printed circuit board 300. The film substrate 210 may at least partially overlap with the non-display area NDA of the display substrate 100. The film substrate 210 may be electrically connected to a first end of the display substrate 100 and to a first end of the printed circuit board 300. In one or more embodiments, the film substrate 210 may be bent or folded to a side surface of the display substrate 100 (e.g., to be beneath the display substrate 100) by connecting the display substrate 100 and the printed circuit board 300.

The driving chip 220 may be located on the film substrate 210. Signals and driving voltages may be supplied to the pixels PX of the display substrate 100 through the driving chip 220 mounted on the film substrate 210. Although FIG. 1 shows two driving chips 220 mounted on two film substrates 210, respectively, the number of film substrates 210 and driving chips 220 may be appropriately changed depending on the size of the display substrate 100.

In one or more embodiments, the film substrate 210 and the driving chip 220 mounted thereon may be collectively referred to as a chip on film (COF) 200.

The printed circuit board 300 may include a data driver and a timing controller for driving the pixels PX. The printed circuit board 300 may transmit a control signal or the like through the film substrate 210 to the display substrate 100.

The printed circuit board 300 may be implemented as a flexible printed circuit board (FPCB). In this case, the film substrate 210 may be bent, so the printed circuit board 300 may be located on the lower surface of the display substrate 100.

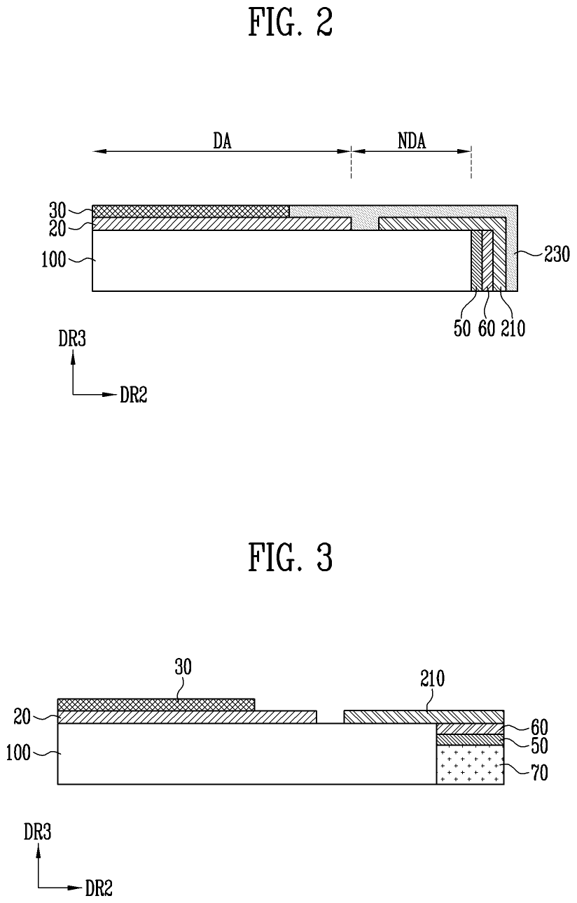

Hereinafter, the side structure of the display device will be mainly described with reference to FIG. 2.

FIG. 2 is a sectional view illustrating a display device in accordance with one or more embodiments.

Referring to FIG. 2, the display device in accordance with one or more embodiments may further include an overcoat layer 20, a protective film 30, and a resin layer 230 that are positioned on the display substrate 100, and may further include a film layer 50 and an adhesive layer 60 that are positioned on a side surface of the display substrate 100.

In one or more embodiments, the thickness of the display substrate 100 may be about 500 μm. The present disclosure is not limited thereto, and the thickness of the display substrate 100 may be changed in various ways according to one or more embodiments.

The overcoat layer 20 may be positioned on the upper surface of the display substrate 100, and may at least partially overlap the display substrate 100. The overcoat layer 20 may be positioned in the display area DA of the display substrate 100. The overcoat layer 20 may make the upper surface of the display substrate 100 flat or substantially flat. The overcoat layer 20 may include transparent material.

The protective film 30 may be positioned on the upper surface of the overcoat layer 20, and may at least partially overlap the overcoat layer 20. The protective film 30 may be positioned in the display area DA of the display substrate 100. The protective film 30 may transmit the image of the display substrate 100, and may protect the display substrate 100 from external impacts and scratches. Further, the protective film 30 may include an anti-reflective coating layer to reduce the reflectance of light that is incident from an outside.

For example, the thickness of each of the overcoat layer 20 and the protective film 30 may range from about 140 μm to about 145 μm. However, the present disclosure is not limited thereto, and the thickness of each of the overcoat layer 20 and the protective film 30 may be changed in various ways according to one or more embodiments.

The resin layer 230 is positioned to cover the entire film substrate 210, and is positioned to cover at least a portion of the overcoat layer 20 and at least a portion of the display substrate 100. The resin layer 230 may be positioned in the non-display area NDA and a portion of the display area DA.

The resin layer 230 may be positioned to contact a side surface of the protective film 30. The upper surface of the resin layer 230 and the upper surface of the protective film 30 may be positioned on substantially the same plane. The resin layer 230 may be positioned to fill a space between the overcoat layer 20 and the film substrate 210. In other words, the resin layer 230 may be positioned to cover a side surface and a portion of the upper surface of the display substrate 100. Thus, the resin layer 230 may reduce or prevent moisture permeation due to air, moisture, etc. that may penetrate the upper surface of the display substrate 100 from the outside.

The resin layer 230 may be provided on the display substrate 100 and the film substrate 210 by a slit nozzle method.

The film substrate 210 may be bent along the side surface of the display substrate 100 in the third direction DR3, together with the resin layer 230.

In the display device according to one or more embodiments, only a portion of the film substrate 210 is located on the upper surface of the display substrate 100, and a remaining portion is bent to the side surface of the display substrate 100, so that a sectional area (or a bezel) of the non-display area NDA may be formed to be relatively narrow.

The film layer 50 is a component of a guide film, which will be described later, and may be positioned between the side surface of the display substrate 100 and the adhesive layer 60 along the second direction DR2. The film layer 50 may be located on a side surface of the display substrate 100 as portions of the resin layer 230 and the film substrate 210 are bent along the third direction DR3. The film layer 50 may include polyethylene terephthalate (PET). The present disclosure is not limited thereto, and the film layer 50 may include various materials constituting plastic.

The adhesive layer 60 is a component of a guide film, which will be described later, and may be positioned between the film layer 50 and a surface of the film substrate 210 with respect to the second direction DR2. In one or more embodiments, the adhesive layer 60 may be an optically clear adhesive layer. The present disclosure is not limited thereto. According to one or more embodiments, the adhesive layer 60 may be replaced with various other adhesive materials.

In some embodiments, the driving chip 220 (see FIG. 1) may be positioned between the adhesive layer 60 and the film substrate 210, or between the film layer 50 and the film substrate 210.

In one or more embodiments, as the resin layer 230 is applied once to the upper surface of the film substrate 210 and to a portion of the upper surface of the display substrate 100, and the resin layer 230 and the film substrate 210 are bent to a side surface of the display substrate 100, a frameless display device may be implemented in a simple manner.

Further, in one or more embodiments, the resin layer 230 may be applied, and the resin layer 230 and the film substrate 210 may be bent to a side surface of the display substrate 100 using the display substrate 100 that is thinner than a conventional display substrate. Thus, a method of applying the resin layer 230 may be applied to various display devices regardless of the thickness of the display substrate 100.

Hereinafter, a method of manufacturing a display device in accordance with one or more embodiments will be described with reference to FIGS. 3 to 10.

FIGS. 3 to 10 are drawings illustrating a method of manufacturing a display device in accordance with one or more embodiments.

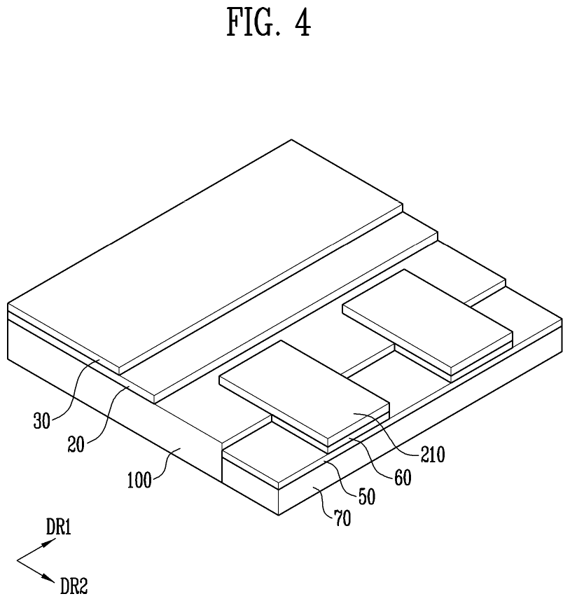

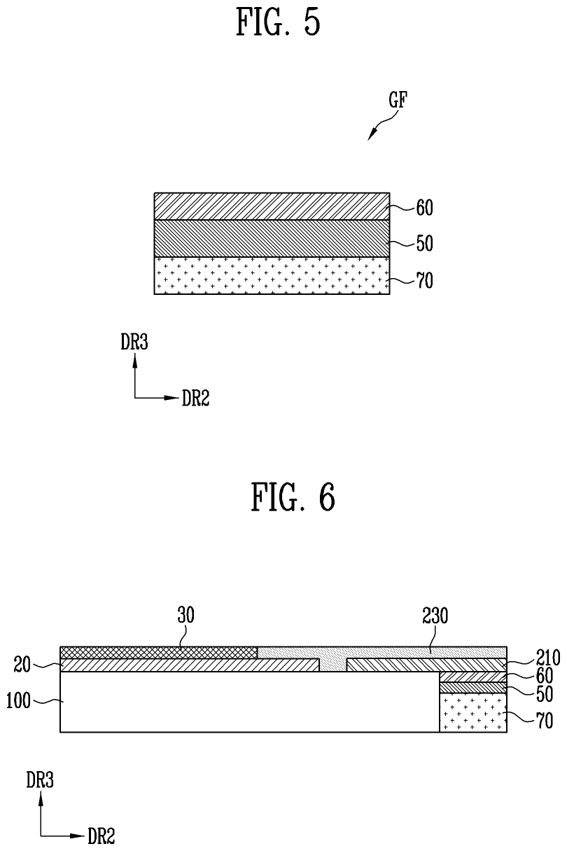

FIGS. 3, 6, and 8 are sectional views illustrating the method of manufacturing the display device, and FIGS. 4, 7, 9, and 10 are perspective views illustrating the method of manufacturing the display device. FIG. 5 is a sectional view illustrating a structure of a guide film used in the method of manufacturing the display device in accordance with one or more embodiments. Hereinafter, it will be described with reference to the sectional view and the perspective view to correspond to each manufacturing method.

Referring to FIGS. 3, 4, and 5, the display substrate 100 and the film substrate 210, which at least partially overlaps the upper surface of the display substrate 100, may be prepared, and a guide film GF (FIG. 5) may be attached to the lower surface of the film substrate 210.

The overcoat layer 20 may be positioned on the upper surface of the display substrate 100, and the protective film 30 may be positioned on the overcoat layer 20. The overcoat layer 20 may be positioned on the upper surface of the display substrate 100 to be spaced apart from the film substrate 210.

The guide film GF may include a film layer 50, an adhesive layer 60, and a support layer 70.

The film layer 50 may be positioned on the upper surface of the support layer 70. In other words, the film layer 50 may be positioned on the support layer 70 along the third direction DR3. For example, the thickness of the film layer 50 may correspond to about 23 μm, but the present disclosure is not limited thereto.

The adhesive layer 60 may be positioned at the uppermost end of the guide film GF. The adhesive layer 60 may attach the film substrate 210 to the guide film GF.

The adhesive layer 60 may be located on a portion corresponding to the film substrate 210 on the upper surface of the guide film GF. For example, the thickness of the adhesive layer 60 may be about 17 μm, but the present disclosure is not limited thereto.

The support layer 70 may be positioned on the lower surface of the film layer 50. In other words, the support layer 70 may be positioned on the lower surface of the film layer 50 along the third direction DR3. For example, the thickness of the support layer 70 may be about 449 μm. However, the present disclosure is not limited thereto, and the thickness of the support layer 70 may be changed in various ways.

In one or more embodiments, the support layer 70 is a liner for keeping the upper surface of the film substrate 210 substantially flat, and the guide film GF may have a thickness that is similar to that of the display substrate 100. For instance, when the thickness of the display substrate 100 is about 500 μm, the thickness of each of the film layer 50 and the adhesive layer 60 may be about 40 μm, and the thickness of the support layer 70 may be about 450 μm.

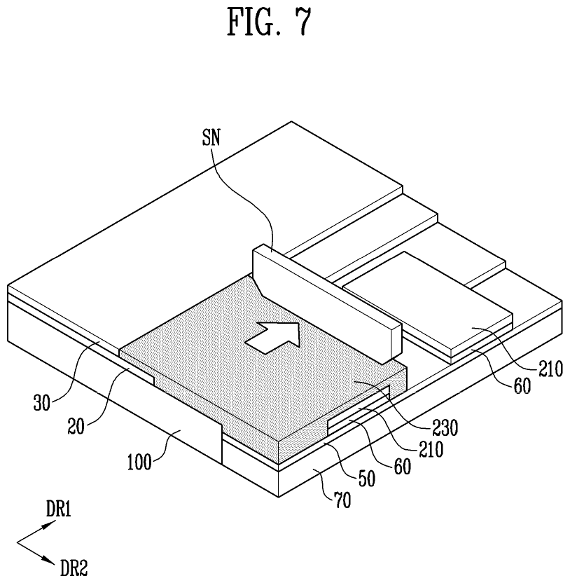

Referring to FIGS. 6 and 7, the resin layer 230 may be applied to the upper surface of the film substrate 210 and the upper surface of a portion of the display substrate 100.

The resin layer 230 may be applied to cover the entire upper surface of the film substrate 210, at least a portion of the overcoat layer 20, and at least a portion of the display substrate 100. The resin layer 230 may be applied to contact a side surface of the protective film 30. The resin layer 230 may be applied to an appropriate thickness so that the upper surface of the resin layer 230 is positioned on substantially the same plane as the upper surface of the protective film 30. For instance, when the thickness of each of the overcoat layer 20 and the protective film 30 is about 140 μm, the upper surface of the display device may be made flat by appropriately adjusting the thickness of the resin layer 230 in the range of about 100 μm to about 170 μm.

In one or more embodiments, the resin layer 230 may be applied to have the viscosity of about 2600 cps. If ultraviolet rays are irradiated for about 0.5 s after the resin layer 230 is applied, the resin layer 230 may be cured so that the upper surface of the display device becomes substantially flat. For example, in case that the resin layer 230 has the viscosity less than about 1000 cps or the viscosity of about 900 cps, if UV rays are irradiated, defects may occur (e.g., the upper surface of the display device may become uneven, or an area to which the resin layer 230 is applied may be cut off).

In one or more embodiments, the resin layer 230 may be applied by the slit nozzle method. A slit nozzle component SN may move along the first direction DR1, and may apply the resin layer 230 to the display substrate 100 and the film substrate 210. The size of the slit nozzle component SN may be variously changed depending on an application area, the size of the display substrate 100, the size of the film substrate 210, and the like. In one or more embodiments, as the resin layer 230 is applied by the slit nozzle method, the application tact time can be reduced, and the planarization of the display device can be suitably realized.

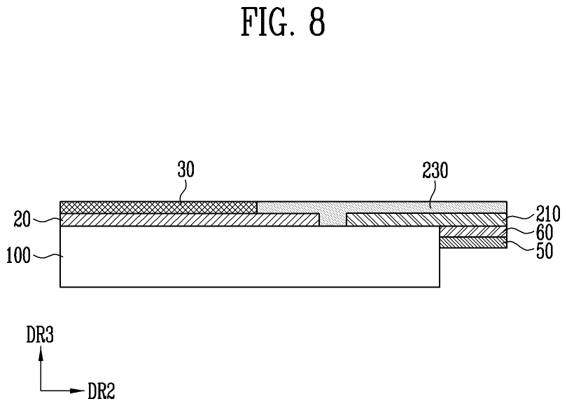

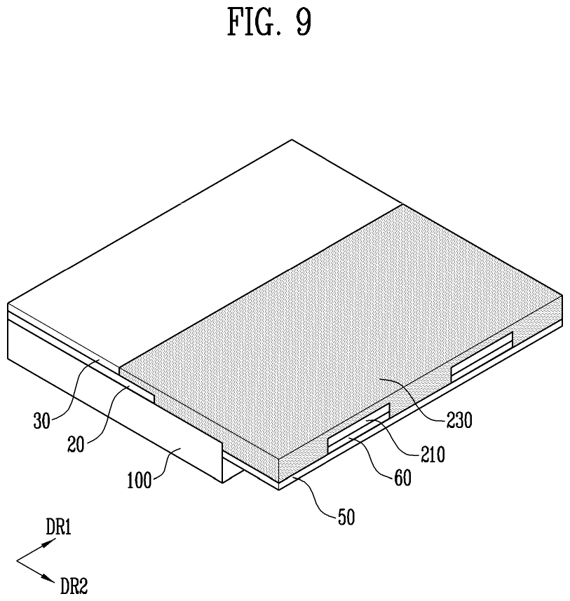

Referring to FIGS. 8 and 9, a portion of the guide film GF may be removed from the lower surface of, or from below, the film substrate 210. In other words, the support layer 70 may be removed from the lower surface of, or from below, the film substrate 210. Thus, the film layer 50 and the adhesive layer 60 may remain on the lower surface of the film substrate 210.

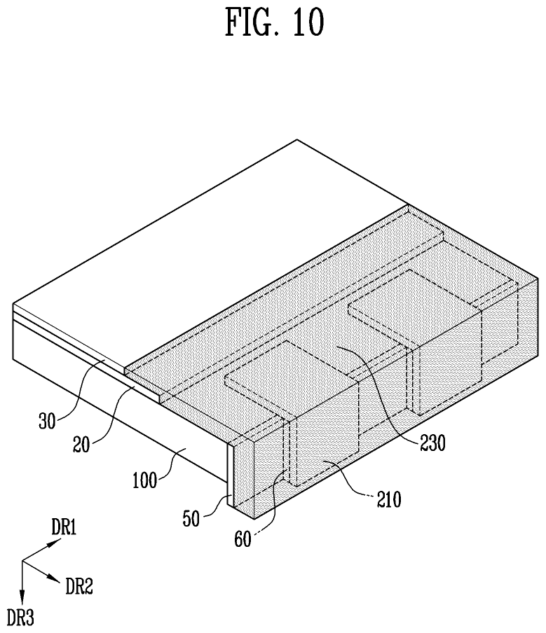

Referring to FIGS. 2 and 10, the resin layer 230, a portion of the guide film GF, and a portion of the film substrate 210 may be bent to the side surface of the display substrate 100. In other words, the film substrate 210 may be bent along the side surface of the display substrate 100 together with the resin layer 230, and the film layer 50 and the adhesive layer 60 may be positioned on the side surface of the display substrate 100.

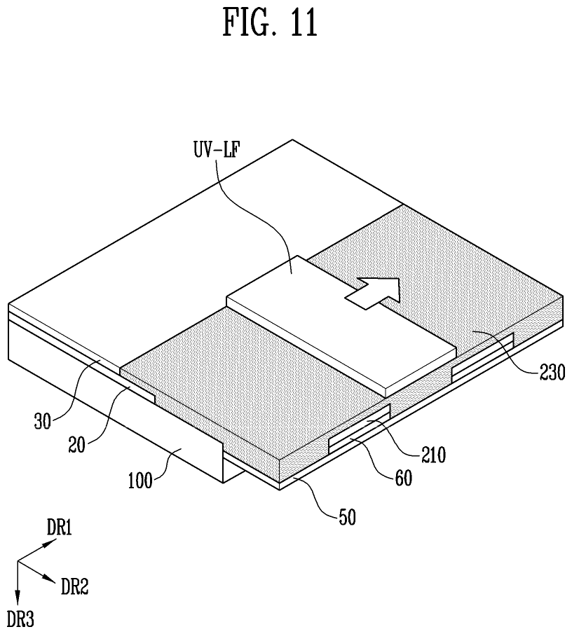

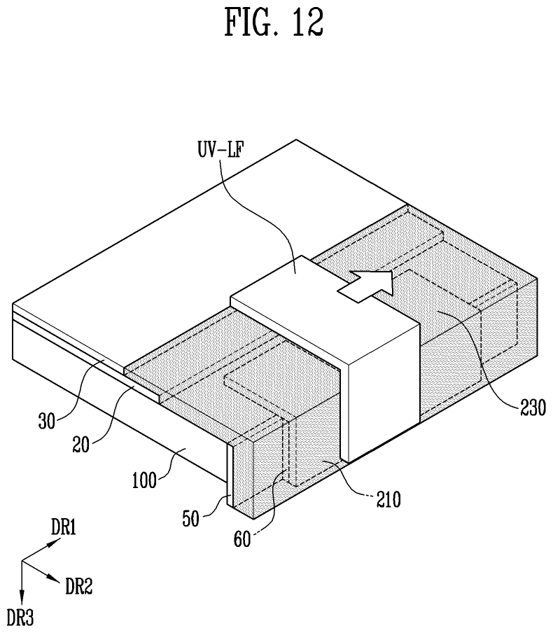

Hereinafter, an additional process of a method of manufacturing a display device in accordance with one or more embodiments will be described with reference to FIGS. 11 and 12.

FIGS. 11 and 12 are perspective views illustrating a method of manufacturing a display device in accordance with one or more embodiments.

Referring to FIGS. 11 and 12, the upper surface of the resin layer 230 may be irradiated with ultraviolet rays using an ultraviolet curing machine UV-LF to cure the resin layer 230. The ultraviolet curing machine UV-LF may move in the first direction DR1 to cure the upper surface of the resin layer 230.

FIG. 11 illustrates a process of curing the resin layer 230 using the ultraviolet curing machine UV-LF, before a portion of the resin layer 230 and a portion of the film substrate 210 are bent to the side surface of the display substrate 100, which has been described with reference to FIG. 10.

In one or more embodiments, after a portion of the guide film GF is removed from the lower portion of, or from below, the film substrate 210, which has been described with reference to FIGS. 8 and 9, and the resin layer 230 is cured through an UV curing process, a portion of the resin layer 230 and a portion of the film substrate 210 may be bent to the side surface of the display substrate 100.

FIG. 12 illustrates a process of curing the resin layer 230 using the ultraviolet curing machine UV-LF, after a portion of the resin layer 230 and a portion of the film substrate 210 are bent to the side surface of the display substrate 100, which has been described with reference to FIG. 10.

In one or more embodiments, after the bending process described with reference to FIG. 10, the resin layer 230 may be cured using the “L”-shaped UV curing machine UV-LF.

Hereinafter, a method of manufacturing a display device using a guide film GF′ and a display device according to one or more embodiments will be described with reference to FIGS. 13 to 17. Because the manufacturing method and the display device illustrated in FIGS. 13 to 17 are similar to those illustrated in FIGS. 2 to 10, differences will be mainly described below.

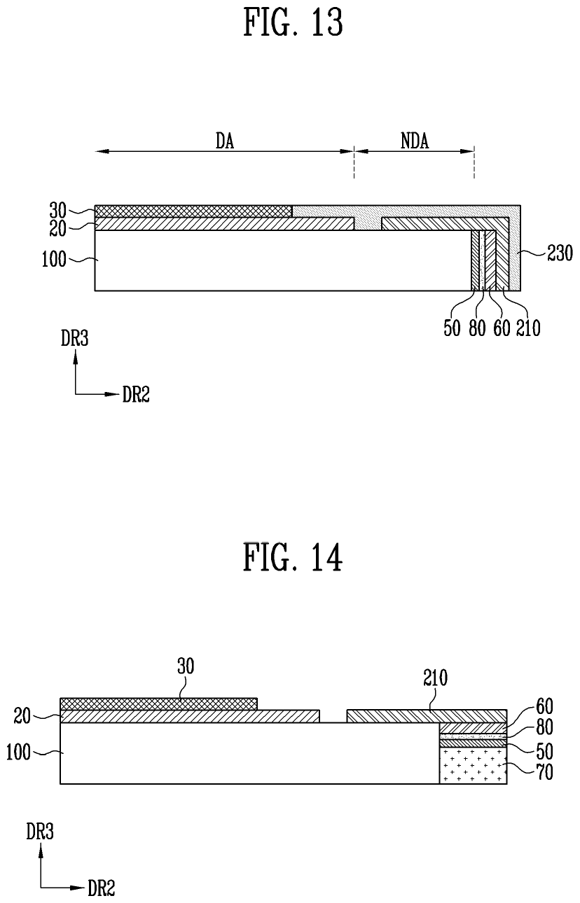

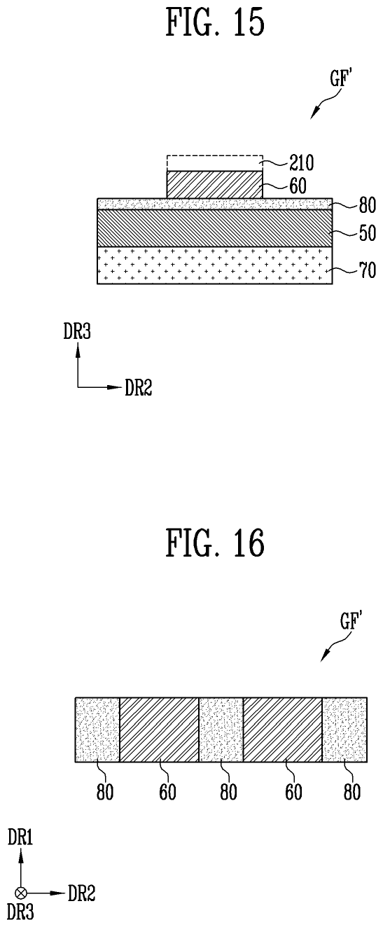

FIG. 13 is a sectional view illustrating a display device in accordance with one or more embodiments, and FIGS. 14 to 17 are drawings illustrating a method of manufacturing a display device in accordance with one or more embodiments. FIG. 15 is a sectional view illustrating a structure of a guide film according to one or more embodiments, and FIG. 16 is a plan view of the guide film of FIG. 15 as viewed from the third direction.

Referring to FIG. 13, a display device in accordance with one or more embodiments may further include a film layer 50, an adhesive layer 60, and an ink layer 80, which are positioned on a side surface of the display substrate 100.

The ink layer 80 is a component of the guide film GF′, and may be positioned between the film layer 50 and the adhesive layer 60 along the second direction DR2. The ink layer 80 may be located on a side surface of the display substrate 100 as portions of the resin layer 230 and the film substrate 210 are bent along the third direction DR3. The ink layer 80 may include a black material through which light is not transmitted.

Referring to FIGS. 14, 15, and 16, the display substrate 100 and the film substrate 210 at least partially overlapping the upper surface of the display substrate 100 may be prepared, and the guide film GF′ may be attached to the lower surface of the film substrate 210.

The guide film GF′ may include a film layer 50, an adhesive layer 60, a support layer 70, and an ink layer 80.

The ink layer 80 may be positioned on the upper surface of the film layer 50. In other words, the ink layer 80 may be positioned on the film layer 50 along the third direction DR3. For example, the thickness of the ink layer 80 may correspond to about 1 μm, but the present disclosure is not limited thereto.

The adhesive layer 60 positioned on the ink layer 80 may be positioned on a portion of the ink layer 80 to overlap the film substrate 210. Thus, when the guide film GF′ is viewed from the third direction DR3, as illustrated in FIG. 16, it may be understood that the ink layer 80 and the adhesive layer 60 intersect along the second direction DR2. In some embodiments, the adhesive layer 60 may be positioned over the entire surface of the ink layer 80.

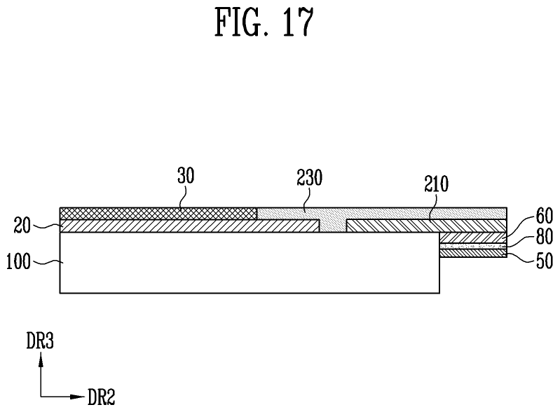

Referring to FIG. 17, a portion of the guide film GF′ may be removed from the lower surface of, or from beneath, the film substrate 210. In other words, the support layer 70 may be removed from beneath the film substrate 210. Thus, the film layer 50, the adhesive layer 60, and the ink layer 80 may remain on the lower surface of the film substrate 210.

Subsequently, the display device illustrated in FIG. 13 may be manufactured by bending the resin layer 230, a portion of the guide film GF′, and a portion of the film substrate 210 to the side surface of the display substrate 100. Further, as illustrated in FIGS. 11 and 12, the resin layer 230 may be cured by irradiating ultraviolet rays onto the resin layer 230 before or after the bending process.

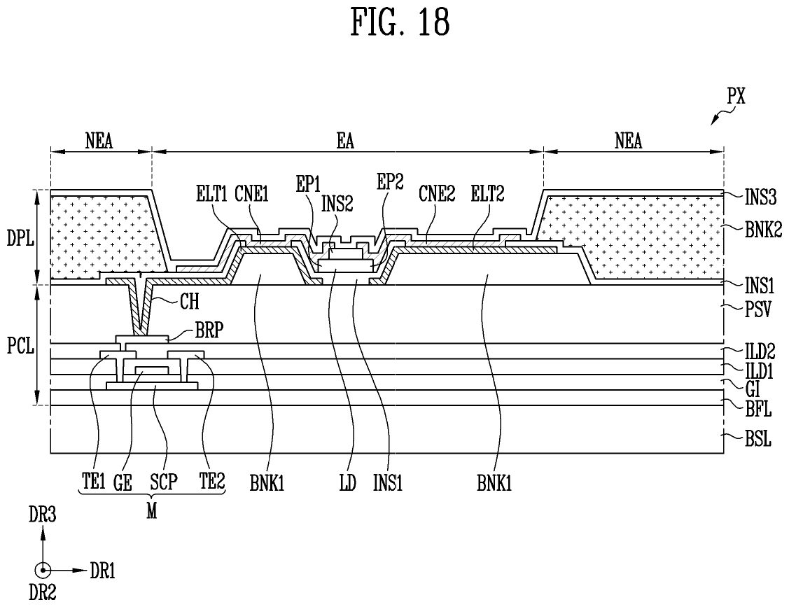

Hereinafter, the pixel structure of a display device in accordance with one or more embodiments will be described with reference to FIG. 18.

FIG. 18 is a sectional view illustrating a pixel of a display device in accordance with one or more embodiments.

The pixel PX of the display device in accordance with one or more embodiments may include a base layer BSL, a pixel circuit layer PCL positioned on a surface of the base layer BSL, and a display element layer DPL. Further, the display area DA of FIG. 1 may include the pixel circuit layer PCL located on a surface of the base layer BSL, and the display element layer DPL located on the pixel circuit layer PCL. However, the mutual position of the pixel circuit layer PCL and the display element layer DPL on the base layer BSL may vary according to one or more embodiments.

The pixel circuit layer PCL may include at least one transistor M, a storage capacitor, and a plurality of lines connected thereto. Furthermore, the pixel circuit layer PCL may include a buffer layer BFL, a gate insulating layer GI, a first interlayer insulating layer ILD1, a second interlayer insulating layer ILD2, and/or a passivation layer PSV, which are successively stacked on a surface of the base layer BSL.

The buffer layer BFL positioned on the entire surface of the base layer BSL and may include an inorganic insulating material. The buffer layer BFL may reduce or prevent impurities from diffusing into the transistor M, the capacitor, etc.

A semiconductor layer is positioned on the buffer layer BFL. The semiconductor layer includes a semiconductor pattern SCP of the transistor M. The semiconductor pattern SCP may include a channel area overlapping a first gate electrode GE, which will be described later, and a source area and a drain area located on respective sides of the channel area. The semiconductor pattern SCP may be formed of poly crystalline silicon, amorphous silicon, an oxide semiconductor, or the like.

The gate insulating layer GI is positioned on the semiconductor layer. The gate insulating layer GI may include an inorganic material including silicon oxide (SiOx), silicon nitride (SiNx), silicon oxynitride (SiOxNy), or the like. However, the present disclosure is not limited thereto. In some embodiments, the gate insulating layer GI may be an organic insulating layer including an organic material.

A gate conductor is positioned on the gate insulating layer GI. The gate conductor includes a first gate electrode GE. The first gate electrode GE may be positioned to overlap the channel area of the first semiconductor pattern SCP. The gate conductor may include a gate electrode of each of the plurality of transistors included in the pixel circuit layer PCL, one electrode of the storage capacitor, a gate line, etc.

A first interlayer insulating layer ILD1 is positioned on the gate conductor. The first interlayer insulating layer ILD1 may include the same material as the gate insulating layer GI, or may include at least one of the exemplified materials in the gate insulating layer GI. For instance, the first interlayer insulating layer ILD1 may be an inorganic insulating layer including inorganic material.

A first data conductor is positioned on the first interlayer insulating layer ILD1. The first data conductor includes a first electrode TE1 and a second electrode TE2 of the transistor M. The first electrode TE1 may be a drain electrode connected to the drain area of the first semiconductor pattern SCP, and the second electrode TE2 may be a source electrode connected to the source area of the first semiconductor pattern SCP. Contrastingly, the first electrode TE1 may be the source electrode of the transistor M, and the second electrode TE2 may be the drain electrode. The first data conductor may include a first electrode TE1 and a second electrode TE2 of each transistor M among the plurality of transistors, and may include another electrode of the storage capacitor, a data line, and the like.

A second interlayer insulating layer ILD2 is positioned on the first data conductor. The second interlayer insulating layer ILD2 may include at least one of silicon oxide (SiOx), silicon nitride (SiNx), and silicon oxynitride (SiOxNy). In one or more embodiments, the second interlayer insulating layer ILD2 may be an organic insulating layer including organic material.

A second data conductor is positioned on the second interlayer insulating layer ILD2. The second data conductor includes a bridge pattern BRP connecting the pixel circuit layer PCL and the display element layer DPL. The second data conductor may further include a driving voltage line, a driving low voltage line, and the like. The bridge pattern BRP may be connected to a first electrode ELT1 of a light emitting element LD of each pixel PX through a contact hole CH. For instance, the light emitting element LD may be an organic light emitting diode or at least one subminiature inorganic light emitting diode. For convenience, in the following embodiments, the light emitting element LD has been described as a subminiature inorganic light emitting diode.

A passivation layer PSV is positioned on the second data conductor. The passivation layer PSV may include at least one organic insulating layer, and may substantially planarize the surface of the pixel circuit layer PCL. The passivation layer PSV may be formed in a single-layer structure or a multilayer structure, and may include an inorganic insulating material or an organic insulating material. For example, the passivation layer PSV may include at least one of polyacrylates resin, epoxy resin, phenolic resin, polyamides resin, and polyimides resin.

The display element layer DPL is positioned on the pixel circuit layer PCL including the passivation layer PSV. The contact hole CH of the passivation layer PSV may connect the bridge pattern BRP of the pixel circuit layer PCL and the first electrode ELT1 of the display element layer DPL.

The display element layer DPL includes the light emitting element LD of the pixels PX, and electrodes connected to the light emitting element LD. The light emitting element LD may be a subminiature inorganic light emitting diode having a relatively small size corresponding to a range from a nano-scale size to a micro-scale size and formed by growing a nitride-based semiconductor.

The display element layer DPL includes a first bank BNK1, a second bank BNK2, a first electrode ELT1, a second electrode ELT2, a first insulating layer INS1, a second insulating layer INS2, a first contact electrode CNE1, a second contact electrode CNE2, and a third insulating layer INS3.

The first bank BNK1 is positioned on the passivation layer PSV. The first bank BNK1 may be positioned in an area (e.g., an emission area EA) in which light is emitted from each pixel PX. The first bank BNK1 may be located under a portion of each of, or a respective one of, the first and second electrodes ELT1 and ELT2 to guide light emitted from the light emitting element LD in an image display direction of the display panel (e.g., the upper direction of each pixel PX, the third direction DR3), so a portion of each of the first and second electrodes ELT1 and ELT2 may protrude upwards (e.g., in the third direction DR3). The first bank BNK1 may include an inorganic insulating layer made of inorganic material or an organic insulating layer made of organic material. In one or more embodiments, the first bank BNK1 may include a single organic insulating layer or a single inorganic insulating layer, but the present disclosure is not limited thereto.

The second bank BNK2 is positioned on, or above, the passivation layer PSV. The second bank BNK2 is a structure that divides the emission area EA of each of the pixels PX, and may be positioned in a non-emission area NEA of each pixel PX (e.g., respectively) and in a non-emission area NEA between the pixels PX to surround the emission area EA of each pixel PX. For example, the second bank BNK2 may be a pixel-defining layer or a dam structure. The second bank BNK2 may be configured to include at least one light-shielding material, reflective material.

Each of the first and second electrodes ELT1 and ELT2 is positioned on the first bank BNK1, or on a respective first bank BNK1, and has a surface corresponding to the shape of the first bank BNK1. The first electrode ELT1 and the second electrode ELT2 may include a material having a substantially uniform reflectance. Thus, the light emitted from the light emitting element LD by the first electrode ELT1 and the second electrode ELT2 may travel in the image display direction (the third direction DR3) of the display panel.

The first electrode ELT1 may be electrically connected to the first electrode TE1 of the transistor M through the contact hole CH formed through the passivation layer PSV. The second electrode ELT2 may be connected to a driving power source through at least one contact hole formed through the passivation layer PSV in an area that is not shown.

In one or more embodiments, the first electrode ELT1 may be an anode, and the second electrode ELT2 may be a cathode.

The first insulating layer INS1 is positioned between each of the first and second electrodes ELT1 and ELT2 and the passivation layer PSV. The first insulating layer INS1 may fill a space between the light emitting element LD and the passivation layer PSV to stably support the light emitting element LD. The first insulating layer INS1 may include at least one of an inorganic insulating layer and an organic insulating layer, and may be formed in a single-layer structure or a multilayer structure.

The light emitting element LD is positioned on the first insulating layer INS1. At least one light emitting element LD may be located between the first electrode ELT1 and the second electrode ELT2. In some embodiments, a plurality of light emitting elements LD may be located between the first electrode ELT1 and the second electrode ELT2, and the plurality of light emitting elements LD may be connected to each other in parallel.

A second insulating layer INS2 is positioned on a portion of the light emitting element LD. The second insulating layer INS2 may cover a portion of the upper surface of each of the light emitting elements LD, and may expose the first and second ends EP1 and EP2 of the light emitting element LD. The second insulating layer INS2 may stably fix the light emitting element LD. In case that an empty space is present between the first insulating layer INS1 and the light emitting element LD before the second insulating layer INS2 is formed, the empty space may be at least partially filled by the second insulating layer INS2.

A first contact electrode CNE1 is positioned on the first electrode ELT1 to electrically and physically connect the first electrode ELT1 and one (e.g. the first end EP1) of both ends of the light emitting element LD. The first contact electrode CNE1 may be positioned to overlap a portion of the first insulating layer INS1, the second insulating layer INS2, and the light emitting element LD. The first insulating layer INS1 (e.g., a portion thereof) may be removed from the portion where the first electrode ELT1 and the first contact electrode CNE1 are connected (e.g., the portion where the first electrode ELT1 and the first contact electrode CNE1 directly contact each other).

A second contact electrode CNE2 is positioned on the second electrode ELT2 to electrically and physically connect the second electrode ELT2 and one (e.g. the second end EP2) of the ends of the light emitting element LD. The second contact electrode CNE2 may be positioned to overlap a portion of the first insulating layer INS1, the second insulating layer INS2, and the light emitting element LD. The first insulating layer INS1 (e.g., a portion thereof) may be removed from the portion where the second electrode ELT2 and the second contact electrode CNE2 are connected (e.g., the portion where the second electrode ELT2 and the second contact electrode CNE2 directly contact each other).

The first contact electrode CNE1 and the second contact electrode CNE2 may be formed of a transparent conductive material. For instance, the first contact electrode CNE1 and the second contact electrode CNE2 may include a material such as indium tin oxide (ITO), indium zinc oxide (IZO), or indium tin zinc oxide (ITZO). Thus, the light emitted from the light emitting element LD and reflected by the first electrode ELT1 and the second electrode ELT2 may travel in the image display direction (the third direction DR3) of the display panel.

A third insulating layer INS3 is positioned on the first contact electrode CNE1, the second contact electrode CNE2, and the second bank BNK2. The third insulating layer INS3 may include at least one organic layer and inorganic layer, and may be completely positioned to cover the surface of the display element layer DPL.

While various embodiments have been described above, those skilled in the art will appreciate that various modifications, additions and substitutions are possible, without departing from the scope and spirit of the present disclosure.

Therefore, the embodiments disclosed in this specification are only for illustrative purposes rather than limiting the technical spirit. The scope must be defined by the accompanying claims, with functional equivalents thereof to be included therein.

According to one or more embodiments, it is possible to implement a frameless display device and a method of manufacturing the display device in a simple manner by applying once a resin layer to each of an upper surface of a film substrate and an upper surface of a portion of a display substrate, and by bending the resin layer and the film substrate to (e.g., toward) a side surface of the display substrate.

In one or more embodiments, as a resin layer is applied by a slit nozzle method, an application tact time can be reduced, and the planarization of a display device can be suitably realized.

The aspects of the embodiments are not limited by the foregoing, and other various aspects are anticipated herein.

What is claimed is:

1. A display device comprising:
a display substrate comprising a display area and a non-display area;
a film substrate at least partially overlapping the non-display area of the display substrate;
a driving chip located the film substrate;
a film layer at a side surface of the display substrate;
an adhesive layer between the film layer and a first surface of the film substrate; and
a resin layer covering a second surface of the film substrate and a portion of an upper surface of the display substrate,
wherein a portion of the resin layer and a portion of the film substrate are bent to the side surface of the display substrate.

2. The display device according to claim 1, further comprising:
an overcoat layer above an upper surface of the display substrate, and at least partially overlapping the display substrate; and
a protective film above an upper surface of the overcoat layer, and at least partially overlapping the overcoat layer.

3. The display device according to claim 2, wherein the resin layer covers the second surface of the film substrate and a portion of the overcoat layer, and to contact a side surface of the protective film.

4. The display device according to claim 3, wherein the resin layer fills a space between the overcoat layer and the film substrate.

5. The display device according to claim 4, wherein an upper surface of the resin layer and an upper surface of the protective film are at substantially a same plane.

6. The display device according to claim 1, wherein the film layer comprises polyethylene terephthalate.

7. The display device according to claim 1, wherein the adhesive layer comprises an optically clear adhesive layer.

8. A method of manufacturing a display device, the method comprising:
preparing a display substrate and a film substrate configured to at least partially overlap an upper surface of the display substrate;
attaching a guide film to a lower surface of the film substrate;
applying a resin layer onto an upper surface of the film substrate and a portion of an upper surface of the display substrate;
removing a portion of the guide film; and
bending a portion of the resin layer, a remaining portion of the guide film, and a portion of the film substrate to a side surface of the display substrate.

9. The method according to claim 8, wherein the guide film comprises a support layer, a film layer, and an adhesive layer that are successively stacked, and
wherein the guide film is attached so that an upper surface of the adhesive layer is at the lower surface of the film substrate.

10. The method according to claim 9, wherein the removed portion of the guide film comprises the support layer.

11. The method according to claim 10, wherein applying the resin layer comprises applying the resin layer by a slit nozzle method.

12. The method according to claim 11, further comprising irradiating an upper surface of the resin layer with ultraviolet rays after removing the portion of the guide film.

13. The method according to claim 11, further comprising irradiating the upper surface of the resin layer with ultraviolet rays after bending the remaining portion of the guide film, and the portion of the film substrate to the side surface of the display substrate.

14. The method according to claim 8, wherein the guide film comprises a support layer, a film layer, an ink layer, and an adhesive layer that are successively stacked, and
wherein the guide film is attached so that an upper surface of the adhesive layer is at the lower surface of the film substrate.

15. The method according to claim 14, wherein the removed portion of the guide film comprises the support layer.

16. A display device comprising:
a display substrate comprising a display area and a non-display area;
a film substrate at least partially overlapping the non-display area of the display substrate;
a driving chip located on the film substrate;
a film layer at a side surface of the display substrate;
an adhesive layer between the film layer and a first surface of the film substrate;
an ink layer between the film layer and the adhesive layer; and
a resin layer covering a second surface of the film substrate and a portion of an upper surface of the display substrate,
wherein a portion of the resin layer and a portion of the film substrate are bent to the side surface of the display substrate.

17. The display device according to claim 16, further comprising:
an overcoat layer above the upper surface of the display substrate, and at least partially overlapping the display substrate; and
a protective film above an upper surface of the overcoat layer, and at least partially overlapping the overcoat layer.

18. The display device according to claim 17, wherein the resin layer covers a portion of the overcoat layer, and contacts a side surface of the protective film.

19. The display device according to claim 18, wherein the resin layer fills a space between the overcoat layer and the film substrate.

20. The display device according to claim 19, wherein an upper surface of the resin layer and an upper surface of the protective film are at substantially a same plane.
